(19) United States
(12) Patent Application Publication
(10) Pub. No.: US 2007/0063194 A1
(43) Pub. Date: Mar. 22, 2007

(54) Organic electroluminescent display device for applying to the field of full-color display and method for manufacturing the same

(76) Inventors: Chien-Yuan Feng, Chu-Nan (TW); Ting-Chou Chen, Chu-Nan (TW); Yuan-Chang Tseng, Chu-Nan (TW); Chien-Chih Chiang, Chu-Nan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/475,972

(22) Filed: Jun. 28, 2006

(30) Foreign Application Priority Data
Jun. 30, 2005 (TW) 094122189

(51) Int. Cl. H01L 29/08

(52) U.S. Cl. 257/40

(57) ABSTRACT

The present invention relates to an organic electroluminescent display device for applying to the field of full-color display. The device includes a first electrode provided on the surface of a color filter. A first organic light emitting unit for generating a first light and a fourth organic light emitting unit for generating a fourth light respectively is provided on the surface of the first electrode. The first organic light emitting unit is provided on the vertical extension place of a first photo-resist of the color filter and the first light can pass through the first photo-resist. The fourth organic light emitting unit is provided on the vertical extension place of a second photo-resist and third photo-resist. The fourth light can pass though the second photo-resist and filtered to generate a second color light, pass through the third photo-resist and filtered to generate a third color light. By mixing the first color light, second color light, and third color light, the organic electroluminescent display device with full-color light emitting function is formed.

### FIELD OF THE INVENTION

The present invention is related to an organic electroluminescent display device, and more particularly to an organic electroluminescent display device for applying to the field of full-color display and method for manufacturing the same.

### BACKGROUND OF THE INVENTION

In accordance with various displays, how to achieve the object of full-color display is always the key point for deciding the display development is success or not. For organic electroluminescent display devices (OLED), there are two common ways to achieve full-color function as follows:

1. To provide the organic light emitting element for generating three primary colors (red, green, and blue) respectively and independently (side by side), such three different colors are mixed and collocated with proper ration for generating a full-color display effect. However, the organic light emitting element for generating different color light is made by a lot of times evaporation processes, not only manufacturing more complicated, but also evaporation aligning more difficult. Thus, the yield will decrease and cost will increase.

2. To provide at least one organic light emitting element for generating a white light, such can be collocated with a color filter to show a full-color display effect by filtering color for the white light.

Referring to FIG. 1, a prior art organic electroluminescent display device 200 includes a color filter 10, which provides a black matrix 13 on a substrate 11 and a color filtering layer (or called photo-resist) 15 for filtering color formed on the partial surface of the Black Matrix 13, and the partial surface of the substrate 11 without the Black Matrix 13, such as photo-resist R, G, and B. Further, an overcoat layer 17 or a barrier layer 19 can be selectively provided on the black matrix 13 and color filtering layer 15 for benefiting following processes.

In addition, a first electrode 21 of the organic light emitting element 20 is provided on the surface of the barrier layer 19 or overcoat layer 17, and an organic light emitting unit 23 and a second electrode 25 are provided in order on the partial surface of the first electrode 21. With conducting current through the first electrode 21 and the second electrode 25, the organic light emitting unit 23 emits a white light L. After the white light L passing through the color filtering layer 15, it will be color filtering to form the three primary colors, Green (G), Blue (B), and Red (R), as L1, L2, and L3, to mix and collocate for showing full-color display.

By way of the color filter 10 providing, although the difficulty of the organic light emitting unit 23 production can be efficiently reduced from the times of evaporation and masking, and further being easier for the evaporation aligning; however, according to the widespread wave length of the white light L, it causes the light penetrates through the color-filtering layer 15 badly from the white light L, so as to affect the light brightness and the color saturation of the organic electroluminescent display device 200.

### SUMMARY OF THE INVENTION

Accordingly, how to design a novel organic electroluminescent display device and a method of manufacturing the same with respect to the problems encountered by the above mentioned prior art to effectively reduce process steps and difficulties to improve yields and relatively improve color light penetration and light color saturation thereof is the key point of the present invention.

It is a primary object of the present invention to provide an organic electroluminescent display device for applying to the field of full-color display, which can achieve the purpose of showing the full-color display effect by reducing the times of evaporation or masking, such that is not only to simplify the process, but also efficiently increase the yield of production.

It is a secondary object of the present invention to provide an organic electroluminescent display device for applying to the field of full-color display, which is not only used to improve the transmission rate of each light for the color filter, but also used to enhance the light saturation.

It is another object of the present invention to provide a method of manufacturing of an organic electroluminescent display device for applying in full color display, which is not only to simplify the difficulty of alignment and process, but also efficiently increase the light transmission and color saturation, and then reduce the power consumption and extend the lifetime of elements.

To achieve the above mentioned objects, the present invention provides an organic electroluminescent display device for applying to the field of full-color display, comprising: a color filter comprising a first photo-resist, second photo-resist, and third photo-resist on the partial surface of a substrate; at least one first electrode provided on the partial surface of the color filter; at least one first organic light emitting unit comprising a first organic light emitting layer provided on the surface of the first electrode of the vertical extension place of the first photo-resist and generating a first light; at least one fourth organic light emitting unit comprising a fourth organic light emitting layer formed by a second organic light emitting layer and a third organic light emitting layer stacked, the fourth organic light emitting layer provided on the surface of the first electrode of the vertical extension place of the second photo-resist and the third photo-resist, wherein the fourth organic light emitting unit can generate a fourth light; and at least one second electrode provided on the surfaces of the first organic light emitting unit and the fourth organic light emitting unit.

Further, to achieve the above mentioned objects, the present invention further provides a method of manufacturing an organic electroluminescent display device for applying to the field of full-color display comprising following steps: forming at least one first electrode on the partial surface of a color filter; positioning a first mask on the vertical extension place of a second photo-resist and a third photo-resist of the color filter; using a first evaporation source to form a first organic light emitting layer of a first organic light emitting unit on the surface of the first electrode of the vertical extension place of a first photo-resist, wherein the first organic light emitting unit can generate a first light; positioning a second mask on the vertical extension place of the first photo-resist, and using a second evaporation source to form a second organic light emitting layer on the surface of the first electrode of the vertical extension place of the second photo-resist and the third photo-resist; using a third evaporation source to form a third organic light emitting layer on the surface of the second organic light emitting layer, wherein the second organic light emitting layer and the third organic light emitting layer are arranged by means of stacking to form a fourth organic light emitting layer of a fourth organic light emitting unit which can generate a fourth light; and forming at least one second electrode on the surfaces of the first organic light emitting unit and the fourth organic light emitting unit.

### BRIEF DESCRIPTION OF DRAWINGS

FIG. 1 depicts a schematic cross sectional view of a prior art organic electroluminescent display device;

FIG. 2 depicts a schematic cross sectional view of an organic electroluminescent display device one of an embodiment of the present invention;

FIG. 3A to FIG. 3C depicts respectively schematic cross sectional view in each process step of an embodiment of the present invention;

FIG. 4 depicts a schematic cross sectional view of the process of another embodiment of the present invention;

FIG. 5 depicts a schematic cross sectional view of another embodiment of the present invention; and

FIG. 6 depicts a schematic cross sectional view of another embodiment of the present invention.

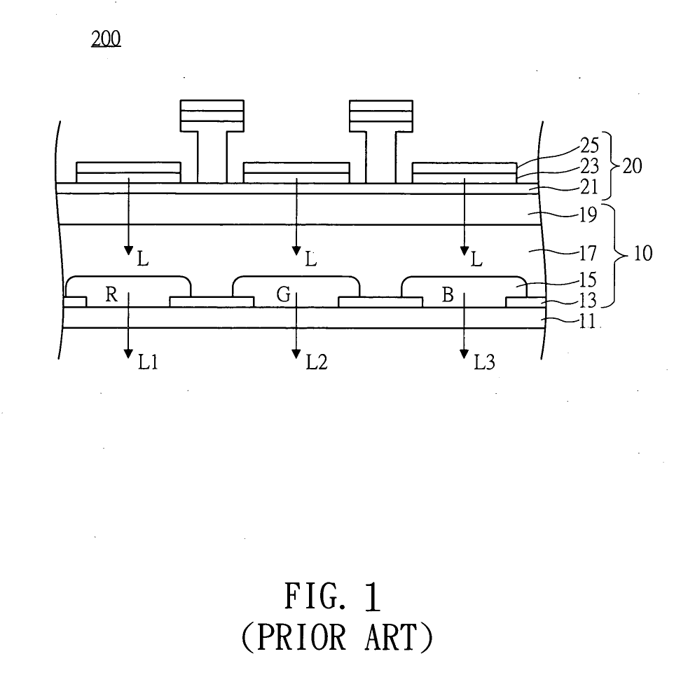

### DETAILED DESCRIPTION OF THE INVENTION

The structural features and the effects to be achieved may further be understood and appreciated by reference to the presently preferred embodiments together with the detailed description.

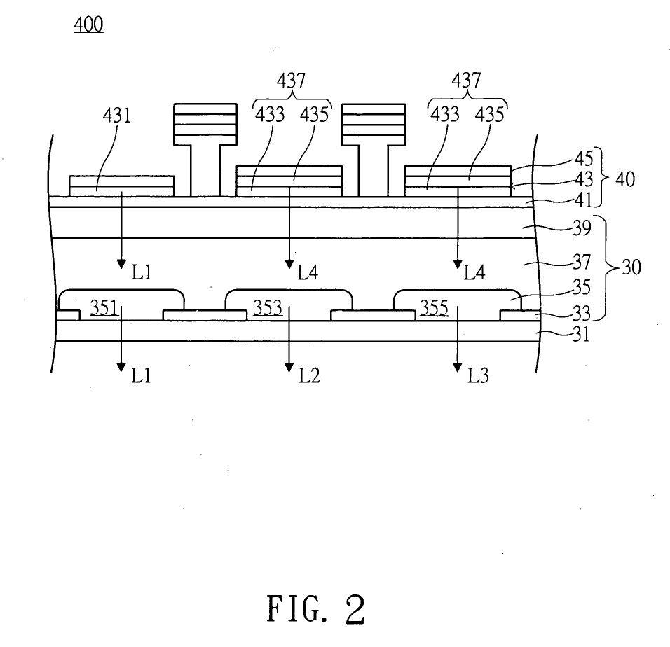

Referring to FIG. 2, is a schematic cross sectional view of one embodiment of the present invention. The organic electroluminescent (OLED) display device 400 comprises at least one organic light emitting element 40 on the partial surface of a color filter 30. The color filter 30 comprises at least one black matrix 33 on the partial surface of a substrate 31. A color filtering layer (or photo-resist) 35 with color filtering function is provided on the partial surface of the Black Matrix 33, and the partial surface of the substrate 31 without the Black Matrix 33. The color filtering layer 35 comprises a first photo-resist (such as R) 351, second photo-resist (such as G) 353, and third photo-resist (such as B) 355. Further, at least one flat barrier unit, such as an overcoat layer 37, a barrier layer 39, or the both, is covered on the black matrix 33 and the color filtering layer 35.

At least one organic light emitting element 40 is provided on the partial surface of the overcoat layer 37 or the barrier layer 39 of the color filter 30. The first electrode 41 of the organic light emitting element 40 and the overcoat layer 37 or the barrier layer 39 are connected. Further, an organic light emitting unit 43 and a second electrode 45 are provided in order on the first electrode 41. The organic light emitting unit 43 comprises at least one first organic light emitting unit 431 and at least one fourth organic light emitting unit 437. Besides, the first organic light emitting unit 431 comprises at least one first organic light emitting layer, and the fourth light emitting unit 437 comprises at least one fourth light emitting layer. The fourth light emitting layer is formed by a plurality of organic light emitting layers or organic light emitting units stacked. For example, the fourth organic light emitting unit 437 includes the second organic light emitting layer 433 and the third organic light emitting layer 435. Wherein, the first organic light emitting unit 431 is provided on the surface of partial first electrode 41, and the fourth light emitting layer 437 is provided on the surface of the first electrode 41 without the first organic light emitting unit 431 provided. When an operation current is supplied between the first electrode 41 and the second electrode 45, the first organic light emitting unit 431 generates a first light L1, and the fourth organic light emitting unit 437 generates a fourth light L4 mixed and formed by a color light generated by the second organic light emitting layer 433 and third organic light emitting layer 435. Besides, the first light L1 and fourth light L4 are complementary.

The first organic light emitting unit 431 is provided on the vertical extension place of the first photo-resist 351 of the color filter 30, and the fourth organic light emitting unit 437 is provided on the vertical extension place of the second photo-resist 353 and the third photo-resist 355 of the color filter 30. Accordingly, the first light L1 generated by the first organic light emitting unit 431 passes through the first photo-resist 351 and filtered for generating a first color light L1. The fourth light L4 generated by the fourth organic light emitting unit 437, will respectively pass through the second photo-resist 353 and the third photo-resist 355, and filtered for generating a second color light L2 and a third color light L3 correspondingly. By mixing and collocating the first color light L1, second color light L2, and third color light L3 will shows a full-color display effect on the organic electroluminescent display device 400.

For example, the first light L1 generated by the first organic light emitting unit 431 is a blue light, and the second organic light emitting layer 433 and the third organic light emitting layer 435 are respectively as an organic light emitting layer with generating a green light and a red light. The fourth organic light emitting layer of the fourth organic light emitting unit 437 is arranged by the second organic light emitting layer 433 and the third organic light emitting layer 435 stacked. Therefore, the fourth light L4 generated by the fourth organic light emitting unit 437 is mixed by a green light and a red light to form an orange light. Besides, the first photo-resist 351, the second photo-resist 353, and the third photo-resist 355 are respectively as a blue photo-resist (351), a green photo-resist (353), and a red photo-resist (355), or as a blue photo-resist (351), a red photo-resist (353), and a green photo-resist (355). Therefore, the first light L1 (blue light) filtered from the first photo-resist (blue photo-resist) 351, will still remain to bring a first colored light L1 (blue light); and the fourth light L4 (orange light) respectively filtered from the second photo-resist (green photo-resist) 353 and the third photo-resist (red photo-resist) 355, will bring a second color light L2 (green light) and a third color light L3 (red light). By mixing the first color light L1 (blue light), second color light L2 (green light), and third color light L3 (red light) with a proper ratio, an object of full-color display from the organic electroluminescent display device 400 can be achieved.

Further, arranged areas of the first organic light emitting layer, the second organic light emitting layer 433, and the third organic light emitting layer 435 of the organic light emitting unit 43, the organic light emitting unit 43, and the color filter layer 35 can be changed for benefiting to the process steps of the organic electroluminescent display device 400.

When the organic light emitting unit 43 provided on the first photo-resist 351 is as an organic light emitting unit with the best light emitting efficiency from one of the organic light emitting units provided on the corresponding places of the photo-resists 351, 353, and 355, such as an organic light emitting unit with generating a green light, the arranged area of the first organic light emitting unit 431 provided on the vertical extension place of the first photo-resist 351 is not larger than the arranged area of the fourth organic light emitting unit 437 provided on the vertical extension place of the second photo-resist 353 and the third photo-resist 355. Thus, the fourth organic light emitting unit 437 is provided with allowing to have a larger error threshold range, so as to benefit for alignment and evaporation process for the organic light emitting unit 43 of the organic electroluminescent display device 400. Of course, when the step of providing the color filter 30 is processing, the arranged area of the first color photo-resist 351 can also be smaller than the arranged areas of the second color photo-resist 353 and the third color photo-resist 355.

Further, with in another embodiment of the present invention, the first light L1 generated by the first organic light emitting unit 431 can be a red light source, and the fourth light L4 generated by the fourth organic light emitting unit 437 can be a teal light source or a cyan light source. The first photo-resist 351, the second photo-resist 353, and the third photo-resist 355 can respectively be a red photo-resist, a green photo-resist, and a blue photo-resist, or a red photo-resist, a blue photo-resist, and a green photo-resist.

Further, the first light L1 generated by the first organic light emitting unit 431 can be a green light, and the fourth light L4 generated by the fourth organic light emitting unit 437 can be a mix from a red light and a blue light, such as a purple light or a magenta light. The first photo-resist 351, the second photo-resist 353, and the third photo-resist 355 can respectively be a green photo-resist, a red photo-resist, and a blue photo-resist, or a green photo-resist, a blue photo-resist, and a red photo-resist.

Since the color filtering layer 35 is as a device with allowing only the specific wavelength field of the light source passing, so as to achieve the purpose of filtering color lights, such as if the first photo-resist 351 is designed for allowing only wavelength 400 nm˜500 nm light source to pass, then the first photo-resist 351 will filter and isolate other light sources from the wavelength field out of 400 nm˜500 nm, but allowing the wavelength 400 nm˜500 nm colored light to pass, which is a blue light as eyeball received, when after the light source as the white light L is going to pass through the first photo-resist 351. However, when the meantime of the color light is filtering, the wavelength field out of 400 nm˜500 nm, will be filtered and isolated by the first photo-resist 351. Therefore, as far as the white light L is concerned by the first photo-resist 351 does not have well transmittance for light source, which is around 25%; thus, comparatively reducing the light intensity.

Oppositely, if the wavelength of the first light L1 is around within the allowance wavelength field of the first photo-resist 351, then as far as the first light L1 is concerned by the first photo-resist 351 have well transmittance, such as the wavelength of the first light L1 is around 420 nm˜470 nm (blue light). Further, when the allowance wavelength field of the first photo-resist 351 is around within 400 nm˜500 nm (blue photo-resist), the most first light L1 will be able to pass through the first photo-resist 351 completely, such as in view of a embodiment of the present invention, the transmittance is up to 80%. Therefore, comparatively the prior art as the organic electroluminescent display device 200 with white light L as the light source, the present invention discloses well light transmittance and intensity.

The fourth light L4 is as a color light source mixed from color lights generated by the second organic light emitting layer 433 and the third organic light emitting layer 435. For example, the fourth organic light emitting unit 437 comprises the second organic light emitting layer 433 and the third organic light emitting layer 435. The second organic light emitting layer 433 and the third organic light emitting layer 435 can respectively emit the second light L2 (green light source) and the third light L3 (red light source). By mixing the second light L2 (green light source) and the third light L3 (red light source) with a proper ratio, it is obtained the fourth light L4 to be as an orange light. After the fourth light L4 (orange light) passing through the second photo-resist (green photo-resist) 353 and the third photo-resist (red photo-resist) 355, will respectively filter and isolate the red light and green light of the fourth light L4 (orange light), and respectively generate the second colored light L2 (green light) and third colored light L3 (red light).

Since the fourth light L4 is mixed from a green light and a red light, in general situations, the wavelength field of a green light is between 500 nm ˜560 nm, and the wavelength field of a red light is between 650 nm˜760 nm. In other words, the fourth light L4 is a light source with two peaks. Besides, the main wavelength fields of the peaks are 500 nm ˜560 nm and 650 nm ˜760 nm. After the fourth light L4 passing through the second photo-resist (green photo-resist) 353, most of the red light (650 nm ˜760 nm) is going to be filtered out, and most of the green light (500 nm ˜560 nm) is going to be allowed to pass through. On the other hand, after the fourth light L4 passing through the third photo-resist (red photo-resist) 355, most of the green light (500 nm ˜560 nm) is going to be filtered out, and most of the red light (650 nm ˜760 nm) is going to be allowed to pass through. Therefore, when the fourth light L4 is with the proportion including half of the red light and half of the green light, comparing with the second photo-resist 353 and the third photo-resist 355, the fourth light L4 has better transmittance than the prior art organic electroluminescent display device 200, such as up to 40%.

According to another embodiment of the present invention, the fourth light L4 generated by the four organic light emitting unit 437 can also be a white light. After the fourth light L4 passing through the second photo-resist 353 and the third photo-resist 355, will respectively generate the second colored light L2 (green light) and the third colored light L3 (red light).

In the above mentioned embodiment of the present invention, the first organic light emitting unit 431 and the fourth organic light emitting unit 437 can selectively comprise a hole injection layer (HIL), a hole transport layer (HTL), an organic light emitting layer, an electron transport layer (ETL), an electron injection layer (EIL), and a combination of the above mentioned elements therein.

Further, in the above mentioned embodiment of the present invention, the fourth organic light emitting layer of the fourth organic light emitting unit 437 is formed by the second organic light emitting layer 433 and the third organic light emitting layer 435 stacked, and the fourth light L4 is mixed from the second light L2 and the third light L3. However, in another embodiment of the present invention, the fourth organic light emitting layer of the fourth organic light emitting unit 437 can consist of an organic light emitting material with directly generating the fourth light L4.

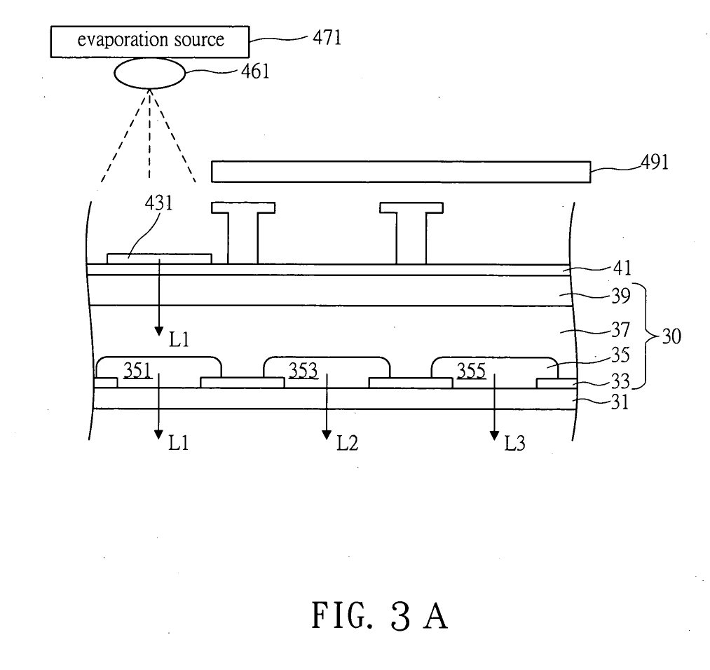

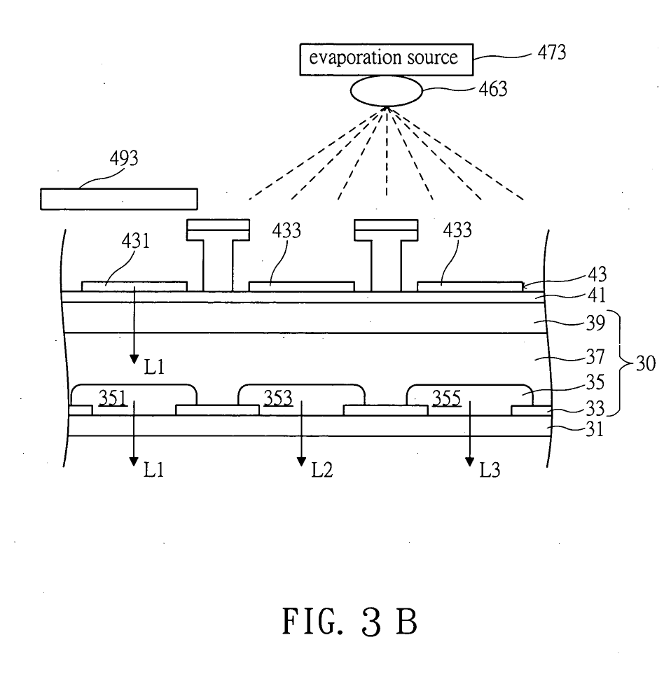

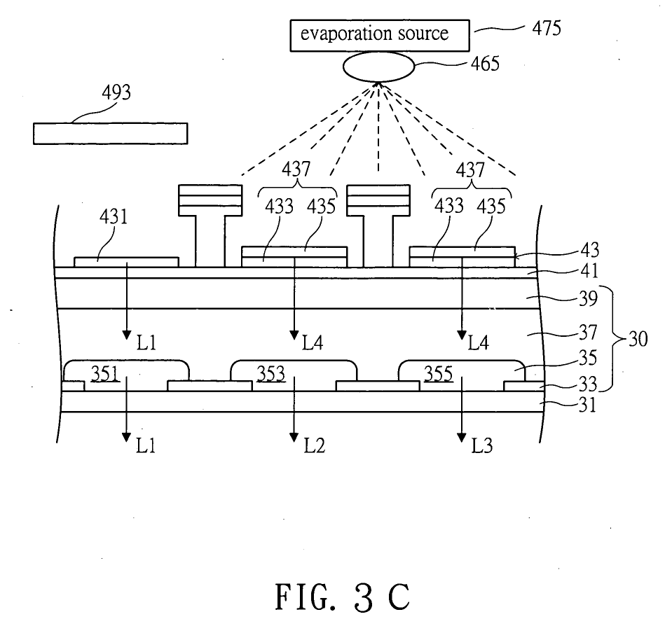

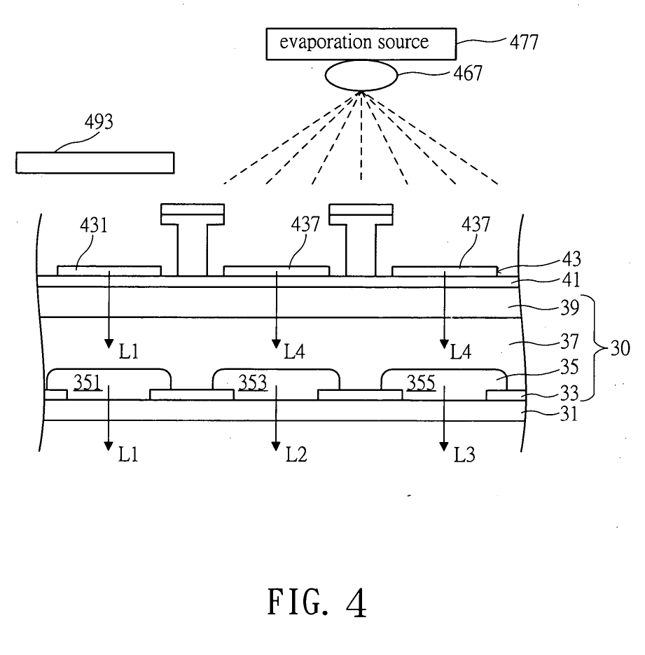

Referring to FIG. 3A, FIG. 3B, FIG. 3C, and FIG. 4 are respectively schematic cross sectional view in each process step of an embodiment of the present invention. As shown, the manufacturing steps of the organic electroluminescent display device of the present invention select to evaporate the hole injection layer and/or the hole transport layer on the first electrode 41 of the organic electroluminescent display device. At least one first organic light emitting unit 431 and fourth organic light emitting unit 437 are formed on the surface of the first electrode 41 or the hole transport layer by means of evaporation. Wherein, the fourth organic light emitting unit 437 comprises a second organic light emitting layer 433 and third organic light emitting layer 435 stacked.

First, partial first electrode 41 was covered and separated by a first mask 491. Evaporating the first organic light emitting layer of the first organic light emitting unit 431 is proceeded by a first evaporation source 471. For example, the first mask 491 is placed on the vertical extension place of the second photo-resist 353 and the third photo-resist 355, and then the evaporation process is proceeded by the first evaporation source 471. The first evaporation source 471 forms the first organic light emitting layer of the first organic light emitting unit 431 on the vertical extension place of the first photo-resist 351. Further, the first evaporation source 47 can be selected as a first organic light emitting material 461 for generating the first light L1, such as derivatives of TPAN, DPAN, DPVBi, PPD, Balq, or DSA for generating a blue light, as shown in FIG. 3A.

After arranging the first organic light emitting layer of the first organic light emitting unit 431, a second mask 493 is placed on the vertical extension place of the first photo-resister 351, and the second organic light emitting layer 433 is formed by the second evaporation source 473 on the vertical extension place of the second photo-resist 353 and third photo-resist 355, as shown in FIG. 3B. After that, the third organic light emitting layer 435 is formed by a third evaporation source 475 on the surface of the second organic light emitting layer 433. The second organic light emitting layer 433 and the third organic light emitting layer 435 are arranged on the vertical extension place of the second photo-resist 353 and third photo-resist 355 to form the fourth organic light emitting unit 437, as shown in FIG. 3C.

Further, since the second organic light emitting unit 433 and the third organic light emitting unit 435 can respectively generate the second light L2 and third light L3, such as green light and red light, the second evaporation source 473 can be selected as a second organic light emitting material 463 for generating the second light L2; for example, the organic light emitting material for generating green light: derivatives of Alq, DPT, Alq3, C6, and so on. The third evaporation source 475 can be selected as the third organic light emitting material 465 for generating the green light L3; for example, the organic light emitting material for generating red light: derivatives of DCM-2, DCJT, and so on.

The fourth organic light emitting unit 437 can be a organic light emitting material for generating the fourth light L4, such as orange light or white light. The fourth organic light emitting layer of the fourth organic light emitting unit 437 is formed by a fourth evaporation source 477 which contain orange organic light emitting material or white organic light emitting material, such as DPP, or mix of the second organic light emitting material 473 and third organic light emitting material 475, such as green light organic light emitting material: derivatives of Alq, DPT, Alq3, C6, and so on and red light organic light emitting material: derivatives of DCM-2, DCJT, and so on. The fourth organic light emitting layer is formed on the surface of the first electrode 41 of the vertical extension place of the second photo-resist 353 and third photo-resist 355 is shown in FIG. 4.

Before forming the first organic light emitting unit 431 and the fourth organic light emitting unit 437, the process of the organic electroluminescent display device can be proceeded. For example, a hole injection layer and a hole transport layer are provided on the surface of the first electrode 41. Besides, after arranging the first organic light emitting unit 431 and the fourth organic light emitting unit 433, the follow-up process of the organic light emitting element 40 can be proceeded. For example, the electron transport layer, the electron injection layer, and the second electrode 45 are provided in order on the first organic light emitting unit 431 and the fourth organic light emitting unit 437.

The organic light emitting unit 43 comprises a hole injection layer, hole transport layer, organic light emitting layer, electron transport layer, and electron injection layer, and the organic light emitting unit 43 can be formed in order on the surface of the first electrode 41. For example, the hole injection layer and hole transport layer are formed in order on the surface of the first electrode 41 by the means of evaporation, and the first organic light emitting unit 431 is formed on the surface of the hole transport layer on the vertical extension place of the first photo-resist 351, while the fourth organic light emitting unit 437 is formed on the surface of the hole transport layer of the vertical extension place of the second photo-resist 353 and third photo-resist 355. The fourth organic light emitting unit 437 comprises the second organic light emitting layer 433 and third organic light emitting layer 435 stacked. The second organic light emitting layer 433 and third organic light emitting layer 435 are provided in order on the surface of first electrode 41, or the third organic light emitting layer 435 is evaporated first, then the second organic light emitting layer 433 is evaporated. The electron transport layer and electron injection layer are formed in order on the surfaces of the first organic light emitting unit 431 and the fourth organic light emitting unit 437 by the means of evaporation to complete arranging the organic light emitting unit 43.

Of course, in another embodiment of the present invention, the arrangement of the fourth organic light emitting unit 437 can be completed first, and the arrangement of the first organic light emitting unit 431 is then proceeded. Further, after completing arranging the first organic light emitting unit 431 and fourth organic light emitting unit 437, the follow-up process of the organic electroluminescent display device 400 can be proceeded, for example, arranging the second electrode 45 on the first organic light emitting unit 431 and the fourth organic light emitting unit 437.

In the above mentioned manufacturing, in comparison with the prior art organic electroluminescent display device using organic light emitting element for generating three primary colors (red, green, and blue) respectively and independently (side-by-side), the times of evaporation and alignment of the organic light emitting unit 43 can be reduced, and the full-color display effect can be achieved as well. Further, by decreasing the times of evaporation and alignment and increasing the evaporation area, the requirement of accuracy in evaporation and alignment can be effectively reduced, and the yield of the organic electroluminescent display device 400 is improved.

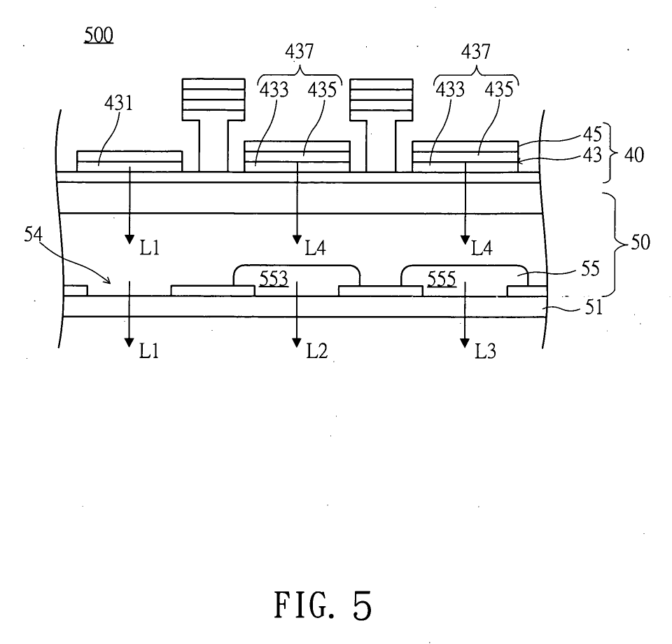

Referring to FIG. 5 is a cross sectional view of another embodiment of the present invention. The organic electroluminescent display device 500 comprises at least one organic light emitting element 40 on the surface of a color filter 50. Wherein, the color filtering layer 55 of the color filter 50 only comprises at least one second photo-resist 553 (such as green photo-resist) and third photo-resist 555 (such as red photo-resist). There is not any photo-resist provided on the position of the first photo-resist (351) within the above mentioned embodiment, but a hollowed part 54 is formed naturally.

The first light L1 generated by the first organic light emitting unit 431 of the organic light emitting element 40 directly passes through the substrate 51 via the hollowed part 54 of the color filter 50. While the fourth light L4 generated by the fourth organic light emitting unit 437 respectively passes through the second photo-resist 553 and third photo-resist 555 and is filtered to generate the second color light L2 (such as green light) and third color light L3 (such as red light). The object of full-color display of the organic electroluminescent display device 500 is achieved. Since the first light L1 passes through the color filter 50 via the hollowed part 54, the penetration and color saturation of the first light L1 can be improved, as well as the process steps of the color filter 50 and production cost can be reduced.

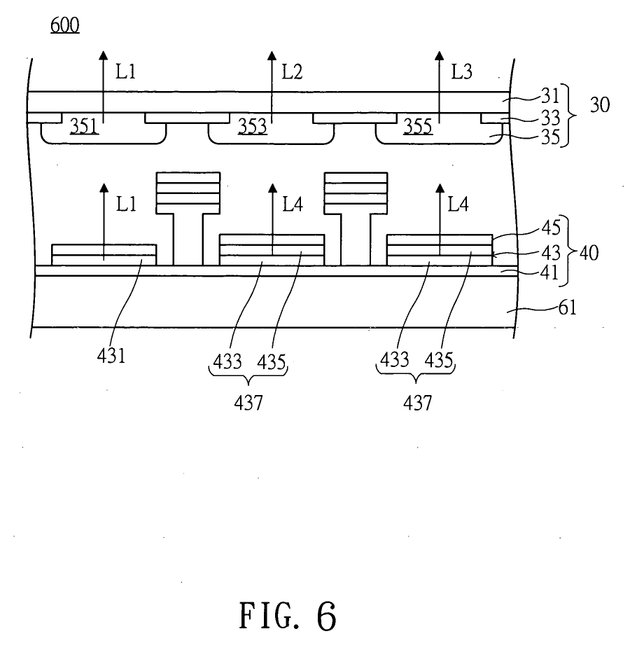

Referring to FIG. 6 is a cross sectional view of an alternate embodiment of the present invention. The organic electroluminescent display device 600 provides at least one organic light emitting element 40 on the surface of a substrate 61. The organic light emitting element 40 comprises at least one first organic light emitting unit 431 and fourth organic light emitting unit 437. Wherein, the fourth organic light emitting unit 437 comprises a second organic light emitting layer 433 and a third organic light emitting layer 435 stacked. Further, a color filter 30 is provided on the top of the organic light emitting element 40. Besides, the first photo-resist 351, the second photo-resist 353, and the third photo-resist 355 of the color filter 30 are respectively provided on the vertical extension place of the first organic light emitting unit 431 and the fourth organic light emitting unit 437 to filter the first light L1 and the fourth light L4 to achieve the object of top emission for the organic electroluminescent display device 600.

The color filter 30 can be arranged on a cap (not shown). Besides, the organic electroluminescent display device 600 needs to be changed to achieve the object of top emission. For example, the second electrode 45 of the organic light emitting element 40 is made of a material with light transparent and conductivity. With this, the first light L1 generated by the first organic light emitting unit 431 and the fourth light L4 generated by the fourth organic light emitting unit 437 can pass through the second electrode 45.

Further, the substrate 61 or color filter 30 comprises at least one thin film transistor (TFT, not shown) and the organic light emitting element 40 is provided on the surface of the substrate 61 or the color filter 30 corresponding to the positions of the thin film transistor. With this, the organic electroluminescent display device 600/400 will be as an active matrix organic electroluminescent display.

The foregoing description is merely one embodiment of present invention and not considered as restrictive. All equivalent variations and modifications in process, method, feature, and spirit in accordance with the appended claims may be made without in any way from the scope of the invention.

1. An organic electroluminescent display device for applying to the field of full-color display, comprising:
a substrate;
a color filter comprising a first photo-resist, a second photo-resist, and a third photo-resist provided on the partial surface of said substrate;
at least one first electrode provided on the partial surface of said color filter;
at least one first organic light emitting unit comprising a first organic light emitting layer provided on the surface of said first electrode of the vertical extension place of said first photo-resist, and generating a first light;
at least one fourth organic light emitting unit comprising a fourth organic light emitting layer formed by a second organic light emitting layer and a third organic light emitting layer stacked, said fourth organic light emitting layer provided on the surface of said first electrode of the vertical extension place of said second photo-resist and said third photo-resist, wherein said fourth organic light emitting unit can generate a fourth light; and
at least one second electrode provided on the surfaces of said first organic light emitting unit and said fourth organic light emitting unit.

2. The display device of claim 1, wherein said first light can pass thought said first photo-resist, and filtered to a first color light; said fourth light can respectively pass thought said second photo-resist and said third photo-resist and filtered to generate a second color light and a third color light.

3. The display device of claim 2, wherein said first light, said second light, and said third light can be respectively selected as one of a red light, a green light, and a blue light.

4. The display device of claim 3, wherein said fourth light can be selected as one of orange light, yellow light, and white light.

5. The display device of claim 1, wherein said organic light emitting unit provided on said first photo-resist is with best light emitting efficiency, and the arranged area of said first organic light emitting unit provided on the vertical extension place of said first photo-resist is smaller than the arranged area of said fourth organic light emitting unit provided on the vertical extension place of said second photo-resist and said third photo-resist.

6. The display device of claim 5, wherein the arranged area of the first organic light emitting unit is smaller than the arranged areas of the second color photo-resist and the said third color photo-resist.

7. The display device of claim 1, wherein said first photo-resist of said color filter is a hollowed part.

8. The display device of claim 1, wherein said first organic light emitting unit and said fourth organic light emitting unit can be respectively selected by one of a hole injection layer, a hole transport layer, an organic light emitting layer, an electron transport layer, an electron injection layer, and a combination thereof.

9. The display device of claim 1, wherein said fourth organic light emitting layer is mixed of a second organic light emitting material and a third organic light emitting material.

10. The display device of claim 1, wherein said color filter comprises one of at least one overcoat layer, at least one barrier layer, and a combination thereof.

11. The display device of claim 1, wherein said fourth color light is formed by mixing light generated from said second organic light emitting layer and third organic light emitting layer.

12. The display device of claim 1, wherein said color filter comprises at least one thin film transistor.

13. The display device of claim 5, wherein said organic light emitting unit with best light emitting efficiency can generate a green light.

14. The display device of claim 1, wherein said first color light and said fourth color light are complementary.

15. A method of manufacturing an organic electroluminescent display device for applying to the field of full-color display, comprising the steps of:
forming at least one first electrode on the partial surface of a color filter;
positioning a first mask on the vertical extension place of a second photo-resist and a third photo-resist of said color filter;
forming a first organic light emitting layer of a first organic light emitting unit on the surface of said first electrode of the vertical extension place of a first photo-resist by a first evaporation source, wherein said first organic light emitting unit can generate a first light;
positioning a second mask on the vertical extension place of said first photo-resist, and forming a second organic light emitting layer on the surface of said first electrode of the vertical extension place of the second photo-resist and the third photo-resist by a second evaporation source;
forming a third organic light emitting layer on the surface of said second organic light emitting layer by a third evaporation source, wherein said second organic light emitting layer and said third organic light emitting layer are arranged by means of stacking to form a fourth organic light emitting layer of a fourth organic light emitting unit, which can generate a fourth light; and
forming at least one second electrode on the surfaces of said first organic light emitting unit and fourth organic light emitting unit.

16. The manufacturing method of claim 15, wherein the evaporation process order of said first organic light emitting layer can be changed with said second organic light emitting layer and said third organic light emitting layer.

17. The manufacturing method of claim 15, wherein said first organic light emitting unit and said fourth organic light emitting unit further comprises one of at least one hole injection layer, at least one hole transport layer, at least one electron transport layer, at least one electron injection layer, and a combination thereof, said first organic light emitting unit and said fourth organic light emitting unit comprises following steps:
forming said hole injection layer and said hole transport layer in order on the partial surface of said first electrode;
forming said first organic light emitting layer and said second organic light emitting layer respectively on the partial surface of said hole transport layer;
forming said third organic light emitting layer on the surface of said second organic light emitting layer; and
forming said electron transport and said electron injection layer in order on the surface of said first organic light emitting layer and third organic light emitting layer.

18. The manufacturing method of claim 15, wherein said first photo-resist of said color filter is a hollowed part.

19. The manufacturing method of claim 15, wherein said fourth organic light emitting layer can be formed by mixed evaporating from a fourth evaporation source, said fourth evaporation source comprising a second organic light emitting material and a third organic light emitting material.

20. The manufacturing method of claim 16, said organic light emitting unit provided on said first photo-resist is with best light emitting efficiency, and the arranged area of said first organic light emitting unit provided on the vertical extension place of said first photo-resist is smaller than the arranged area of said fourth organic light emitting unit provided on the vertical extension place of said second photo-resist and said third photo-resist.

21. The manufacturing method of claim 20, wherein the arranged area of said first organic light emitting unit is smaller than the arranged area of said second photo-resist and third photo-resist.

22. The manufacturing method of claim 15, wherein said color filter comprises at least one thin film transistor.

23. The manufacturing method of claim 15, wherein said first color light and said fourth color light are complementary.

24. The manufacturing method of claim 20, wherein said organic light emitting unit with best light emitting efficiency can generate a green light.
